(19) United States
(12) Patent Application Publication
(10) Pub. No.: US 2026/0234794 A1
(43) Pub. Date: Aug. 13, 2026

(54) VACUUM-PUMPING AND VACUUM-BREAKING STRUCTURE AND VACUUM BREAKING METHOD FOR LARGE-CHAMBER PECVD

(71) Applicant: Gold Stone (Fujian) Energy Company Limited, Quanzhou (CN)

(72) Inventors: Yusheng YANG, Quanzhou (CN); Hongqing SHAN, Quanzhou (CN); Lixian GUO, Quanzhou (CN); Qing YU, Quanzhou (CN); Yijun LIU, Quanzhou (CN)

(73) Assignee: Gold Stone (Fujian) Energy Company Limited, Quanzhou (CN)

(21) Appl. No.: 19/241,770

(22) Filed: Jun. 18, 2025

(30) Foreign Application Priority Data
Feb. 10, 2025 (CN) 202510142576X

(51) Int. Cl. C23C 16/455; C23C 16/50

(52) U.S. Cl. CPC C23C 16/455; C23C 16/50

(57) ABSTRACT

Vacuum-pumping and vacuum-breaking structure and vacuum breaking method for large-chamber PECVD are provided. The vacuum-pumping and vacuum-breaking structure includes a chamber main body, the chamber main body is provided with several main pumping assemblies in the middle of a bottom, both front and rear sides of the bottom of the chamber main body are respectively provided with several slow-vacuum-pumping and vacuum-breaking assemblies and chamber-bottom vacuum-breaking assemblies at intervals. Each of the slow-vacuum-pumping and vacuum-breaking assemblies includes a first vent pipe, and the first vent pipe is connected to a slow pumping assembly and a nitrogen vacuum-breaking assembly. Each of the chamber-bottom vacuum-breaking assemblies includes a second vent pipe, and the second vent pipe is connected to a nitrogen vacuum-breaking assembly and an air vacuum-breaking assembly. A multi-layer flow-homogenizing assembly configured to reduce flow velocity at a gas outlet is provided above the first vent pipe and the second vent pipe.

### CROSS REFERENCE TO RELATED APPLICATIONS

The present disclosure claims priority to Chinese Patent Application No. 202510142576X filed with the China National Intellectual Property Administration on Feb. 10, 2025, entitled “VACUUM-PUMPING AND VACUUM-BREAKING STRUCTURE AND VACUUM BREAKING METHOD FOR LARGE-CHAMBER PECVD”, the entire contents of which are incorporated herein by reference.

### TECHNICAL FIELD

The present disclosure relates to the field of PECVD devices, and particularly to a vacuum-pumping and vacuum-breaking structure and vacuum breaking method for large-chamber PECVD.

### BACKGROUND ART

In order to meet the demand of high-throughput PECVD, PECVD chambers on the market are gradually enlarged, and volumes of the chambers are increased, which has a great impact on vacuum-breaking and vacuum-pumping cycles and yield rate of the device.

In the prior art, two main-pumping control valves are typically provided in the middle of a bottom of a chamber, and each of the main-pumping control valves is provided with a slow-pumping control valve. Each of the main-pumping control valves is provided with a main-pumping pipe, and the slow-pumping control valve is provided with a slow-pumping pipe. Two vacuum-breaking control valves are provided on each of two sides of the chamber. Each of the vacuum-breaking pipes on the control valve has one end communicating with the inside of the chamber, and the other end communicating with the outside. When performing vacuum pumping on the chamber, the two slow-pumping control valves are opened first, and a gas is evacuated at a small flow rate via the slow-pumping pipes for vacuum pumping, thereby avoiding dither and fall-off of a silicon die. When an atmosphere in the chamber reaches a certain pressure and the silicon die is stable, the main-pumping control valves are opened, and the gas is rapidly evacuated at a large flow rate via the main-pumping pipes for vacuum pumping. When the chamber is subjected to vacuum breaking, the vacuum-breaking control valves are opened directly, and air or compressed air is introduced into the chamber via the vacuum-breaking pipes, thereby realizing the vacuum breaking of the chamber.

Although the existing solution can achieve vacuum-pumping and vacuum-breaking functions, the vacuum-pumping and vacuum-breaking cycles thereof are relatively long, and the high-throughput requirement cannot be met. If the flow rates of gas in vacuum-pumping and vacuum-breaking are increased, it will cause a too large pressure change, and affect stability of the silicon die.

### SUMMARY

The present disclosure aims at providing a vacuum-pumping and vacuum-breaking structure and vacuum breaking method for large-chamber PECVD, where by changing positions of vacuum-breaking pipes and vacuum-pumping pipes and adding flow-homogenizing structures, a velocity of a gas flow is reduced, and yield of silicon dies is improved; and on this basis, the number of vacuum-breaking pipes and vacuum-pumping pipes is increased, and vacuum-pumping and vacuum-breaking are controlled step by step, so that vacuum-pumping and vacuum-breaking cycles of a large-chamber PECVD device can be greatly shortened.

In order to achieve the above objective, the present disclosure adopts following technical solutions.

The present disclosure discloses a vacuum-pumping and vacuum-breaking structure for large-chamber PECVD, including a chamber main body, where the chamber main body is provided with several main pumping assemblies in the middle of a bottom, both front and rear sides of the bottom of the chamber main body are respectively provided with several slow-vacuum-pumping and vacuum-breaking assemblies and chamber-bottom vacuum-breaking assemblies at intervals.

Each of the main pumping assemblies includes a main-pumping pipe and a main-pumping control valve, where the main-pumping pipe has one end communicating with the chamber main body, and the other end communicating with an outside, and the main-pumping control valve is provided on the main-pumping pipe.

Each of the slow-vacuum-pumping and vacuum-breaking assemblies includes a first vent pipe, where the first vent pipe is connected to a chamber, and the first vent pipe is connected with a nitrogen vacuum-breaking pipe and a slow-pumping pipe, where the nitrogen vacuum-breaking pipe is provided with a nitrogen vacuum-breaking valve, and the slow-pumping pipe is provided with a slow-pumping control valve.

Each of the chamber-bottom vacuum-breaking assemblies includes a second vent pipe, where the second vent pipe is connected with a nitrogen vacuum-breaking pipe and an air vacuum-breaking pipe, where the nitrogen vacuum-breaking pipe is provided with a nitrogen vacuum-breaking valve, and the air vacuum-breaking pipe is provided with an air vacuum-breaking valve and an air filter.

A multi-layer flow-homogenizing assembly configured to reduce a flow velocity at a gas outlet is further provided above the first vent pipe and the second vent pipe.

When performing vacuum pumping for the chamber main body, the slow-pumping control valves are opened first, the gas is evacuated at a small flow rate via the slow-pumping pipes for vacuum pumping, and when an atmosphere in the chamber reaches a certain pressure and the silicon die is stable, the main-pumping control valves are opened, and the gas is rapidly evacuated at a large flow rate via the main-pumping pipes for vacuum pumping.

Further, the multi-layer flow-homogenizing assembly includes a chamber-bottom inlet-gas flow-homogenizing plate, a middle-layer flow-homogenizing chamber and an outlet-gas flow-homogenizing chamber that are sequentially stacked from top to bottom, where the chamber-bottom inlet-gas flow-homogenizing plate is provided with first flow-homogenizing holes uniformly, and is located on a spout of the first vent pipe and the second vent pipe, a top surface of the middle-layer flow-homogenizing chamber is provided with second flow-homogenizing holes, a top surface of the outlet-gas flow-homogenizing chamber is provided with third flow-homogenizing holes, and the second flow-homogenizing holes and the third flow-homogenizing holes are staggered, so that the gas flow flows in an “S” shape.

Further, the slow-pumping pipe and the main-pumping pipe communicate with each other, and are connected to an external aspirator pump, and an upper spout of the main-pumping pipe is provide with a baffle for filtering.

Further, both left and right sides of the bottom of the chamber main body are further respectively provided with side nitrogen vacuum-breaking assemblies, where each of the side nitrogen vacuum-breaking assemblies includes a nitrogen vacuum-breaking valve, a side inlet-gas flow-homogenizing chamber and a nitrogen vacuum-breaking pipe, where one end of the nitrogen vacuum-breaking pipe communicates with the chamber through a side flow-homogenizing pipe, and the nitrogen vacuum-breaking valve is provided on the nitrogen vacuum-breaking pipe.

Further, the side flow-homogenizing pipe is in a shape of “L” rotated clockwise by 90 degrees, a side flow-homogenizing plate is provided at a joint of the side flow-homogenizing pipe and the nitrogen vacuum-breaking pipe, the side flow-homogenizing plate is provided with several side inlet-gas flow-homogenizing holes, and a side surface of a corner of the other end of the side flow-homogenizing pipe is provided with side outlet-gas flow-homogenizing holes, where the side outlet-gas flow-homogenizing holes are located below a carrier plate, and the gas flow is parallel to a plane of the carrier plate.

Further, four sets of the side nitrogen vacuum-breaking assemblies are provided, and are symmetrically provided on left and right sides of the bottom of the chamber main body, respectively.

Further, two sets of the main pumping assemblies are provided, and are distributed symmetrically with respect to a front-rear center line of the chamber.

Further, four sets of the slow-vacuum-pumping and vacuum-breaking assemblies are provided, which are a first slow-vacuum-pumping and vacuum-breaking assembly, a second slow-vacuum-pumping and vacuum-breaking assembly, a third slow-vacuum-pumping and vacuum-breaking assembly, and a fourth slow-vacuum-pumping and vacuum-breaking assembly, respectively; and six sets of the chamber-bottom vacuum-breaking assemblies are provided, which are a first chamber-bottom vacuum-breaking assembly, a second chamber-bottom vacuum-breaking assembly, a third chamber-bottom vacuum-breaking assembly, a fourth chamber-bottom vacuum-breaking assembly, a fifth chamber-bottom vacuum-breaking assembly, and a sixth chamber-bottom vacuum-breaking assembly, respectively;
the first chamber-bottom vacuum-breaking assembly and the third chamber-bottom vacuum-breaking assembly are respectively located at two ends of a front side of the chamber, and the second chamber-bottom vacuum-breaking assembly is located in the middle of the front side of the chamber;
the fourth chamber-bottom vacuum-breaking assembly and the sixth chamber-bottom vacuum-breaking assembly are located at two ends of a rear side of the chamber, and the fifth chamber-bottom vacuum-breaking assembly is located in the middle of the rear side of the chamber; and
the first slow-vacuum-pumping and vacuum-breaking assembly is located between the first chamber-bottom vacuum-breaking assembly and the second chamber-bottom vacuum-breaking assembly; the second slow-vacuum-pumping and vacuum-breaking assembly is located between the second chamber-bottom vacuum-breaking assembly and the third chamber-bottom vacuum-breaking assembly; the third slow-vacuum-pumping and vacuum-breaking assembly is located between the fourth chamber-bottom vacuum-breaking assembly and the fifth chamber-bottom vacuum-breaking assembly; and the fourth slow-vacuum-pumping and vacuum-breaking assembly is located between the fifth chamber-bottom vacuum-breaking assembly and the sixth chamber-bottom vacuum-breaking assembly.

The present disclosure further discloses a vacuum breaking method for the above vacuum-pumping and vacuum-breaking structure for large-chamber PECVD, including steps of:
S1, first, simultaneously opening gates of the nitrogen vacuum-breaking valves of the second chamber-bottom vacuum-breaking assembly and the fifth chamber-bottom vacuum-breaking assembly, a vacuum-breaking pressure reaching 100-500 pa;
S2, simultaneously opening gates of the nitrogen vacuum-breaking valves of the first chamber-bottom vacuum-breaking assembly, the third chamber-bottom vacuum-breaking assembly, the fourth chamber-bottom vacuum-breaking assembly, and the sixth chamber-bottom vacuum-breaking assembly, the vacuum-breaking pressure reaching 2,000-2,500 Pa;
S3, simultaneously opening gates of the nitrogen vacuum-breaking valves of four sets of the slow-vacuum-pumping and vacuum-breaking assemblies, the vacuum-breaking pressure reaching 15,000-16,000 Pa;
S4, simultaneously opening the nitrogen vacuum-breaking valves of four sets of the side nitrogen vacuum-breaking assemblies, the vacuum-breaking pressure reaching 30,000 Pa-31,000 Pa; and
S5, simultaneously opening gates of the air vacuum-breaking valves of six sets of the chamber-bottom vacuum-breaking assemblies, the vacuum-breaking pressure reaching atmospheric pressure.

Beneficial effects of the present disclosure are as follows.
1. Compared with the prior art, the present disclosure increases the number of slow-pumping spouts, designs their positions outside a range of the carrier plate, and controls the vacuum pumping step by step, thus significantly reducing dither of the silicon die during initial vacuum pumping while elevating a slow-pumping speed, and improving the yield. The multi-layer flow-homogenizing assemblies are provided at slow-pumping spouts, so that in the chamber main body, the gas undergoes full collision and flow homogenization in the multi-layer flow-homogenizing assemblies, which extends a gas path, and enables the gas to be uniformly dispersed into the chamber main body at a low flow velocity, thereby minimizing the influence on the silicon die.
2. Compared with the prior art, the present disclosure increases the number of vacuum-breaking spouts, and provides multiple steps of vacuum breaking of nitrogen vacuum-breaking and air vacuum-breaking, thus significantly reducing dither of the silicon die during the vacuum breaking while elevating the vacuum-breaking speed, and improving the yield. The multi-layer flow-homogenizing assemblies are provided at vacuum-breaking spouts, so that in the chamber main body, the gas undergoes full collision and flow homogenization in the multi-layer flow-homogenizing assemblies, which extends a gas path, and enables the gas to be uniformly dispersed into the chamber main body at a low flow velocity, thereby minimizing the influence on the silicon die.
3. The present disclosure further adds side vacuum-breaking spouts to further accelerate the vacuum breaking, and adds the side flow-homogenizing pipes at the side vacuum-breaking spouts, so as to discharge an introduced gas from a gas outlet on a side surface of a pipe wall of each side flow-homogenizing pipe, thereby minimizing the influence on the silicon die.

### BRIEF DESCRIPTION OF DRAWINGS

In order to illustrate technical solutions of embodiments of the present disclosure more clearly, drawings which need to be used in the embodiments will be briefly introduced below. It should be understood that the drawings merely show some embodiments of the present disclosure, and thus should not be considered as limitation to the scope, and those ordinarily skilled in the art still could obtain other relevant drawings according to the drawings, without using any inventive efforts.

FIG. 1 is a bottom structural schematic view of the present embodiment.

FIG. 2 is a left structural schematic view of the present embodiment.

FIG. 3 is a right structural schematic view of the present embodiment.

FIG. 4 is a cross-sectional schematic view of a chamber-bottom vacuum-breaking assembly.

FIG. 5 is a cross-sectional schematic view of a side nitrogen vacuum-breaking assembly.

FIG. 6 is a structural schematic view of a middle-layer flow-homogenizing chamber.

FIG. 7 is a structural schematic view of an outlet-gas flow-homogenizing chamber.

FIG. 8 is a top structural schematic view of the present embodiment.

### DESCRIPTION OF REFERENCE SIGNS OF MAIN COMPONENTS

1. chamber main body;
2. main pumping assembly, 21. main-pumping pipe, 22. main-pumping control valve, 23. baffle;
3. slow-vacuum-pumping and vacuum-breaking assembly, 31. first vent pipe, 32. first slow-vacuum-pumping and vacuum-breaking assembly, 33. second slow-vacuum-pumping and vacuum-breaking assembly, 34. third slow-vacuum-pumping and vacuum-breaking assembly, 35. fourth slow-vacuum-pumping and vacuum-breaking assembly;
4. chamber-bottom vacuum-breaking assembly, 41. second vent pipe, 42. first chamber-bottom vacuum-breaking assembly, 43. second chamber-bottom vacuum-breaking assembly, 44. third chamber-bottom vacuum-breaking assembly, 45. fourth chamber-bottom vacuum-breaking assembly, 46. fifth chamber-bottom vacuum-breaking assembly, 47. sixth chamber-bottom vacuum-breaking assembly;
5. side nitrogen vacuum-breaking assembly;
61. nitrogen vacuum-breaking pipe, 62. nitrogen vacuum-breaking valve, 63. slow-pumping pipe, 64. slow-pumping control valve, 65. air vacuum-breaking pipe, 66. air vacuum-breaking valve, 67. air filter;
7. multi-layer flow-homogenizing assembly, 71. inlet-gas flow-homogenizing plate, 72. middle-layer flow-homogenizing chamber, 73. outlet-gas flow-homogenizing chamber, 74. second flow-homogenizing hole, 75. third flow-homogenizing hole;
8. side inlet-gas flow-homogenizing chamber, 81. side inlet-gas flow-homogenizing hole, 82. side outlet-gas flow-homogenizing hole;
9. carrier plate.

### DETAILED DESCRIPTION OF EMBODIMENTS

In order to make objectives, technical solutions and advantages of the embodiments of the present disclosure clearer, technical solutions in the embodiments of the present disclosure will be described clearly and completely below in conjunction with the drawings in the present disclosure. Apparently, only some but not all embodiments of the present disclosure are described. Based on the embodiments in the present disclosure, all of other embodiments obtained by those ordinarily skilled in the art without using any inventive efforts shall fall within the scope of protection of the present disclosure.

In the present disclosure, unless otherwise specified, the use of directional terms such as “upper, lower, left, and right” are generally understood in conjunction with the orientation shown in the drawings and practical application.

Besides, the terms “first” and “second” are merely used for descriptive purpose, but should not be construed as indicating or implying importance in the relativity or implicitly indicating the number of a related technical feature. Thus, defining a feature with “first” or “second” may explicitly or implicitly mean that one or more such features are included. In the description of the present disclosure, “a plurality of” means two or more, unless otherwise explicitly defined.

In the present disclosure, unless otherwise explicitly specified and defined, a first feature being “on” or “under” a second feature may mean that the first feature is in direct contact with the second feature, or the first feature is in indirect contact with the second feature via an intermediary. Moreover, a first feature being “on”, “over” and “above” a second feature may include a case where the first feature is directly above or not directly above the second feature, or merely indicates that the first feature is at a horizontal height larger than that of the second feature. Moreover, a first feature being “under”, “beneath” and “below” a second feature may include a case where the first feature is directly below or not directly below the second feature, or merely indicates that the first feature is at a horizontal height smaller than that of the second feature.

Endpoints and any values of ranges disclosed herein are not limited to the precise ranges or values, and these ranges or values should be understood as encompassing values close to these ranges or values. For numerical ranges, endpoint values of various ranges can be combined with each other, endpoint values of various ranges and individual point values can be combined with each other, and individual point values can be combined with each other to obtain one or more new numerical ranges, which numerical ranges should be construed as being specifically disclosed herein. Herein, the terms “optional” and “optionally” both mean possibly including or not (or possibly being present or possibly being not present).

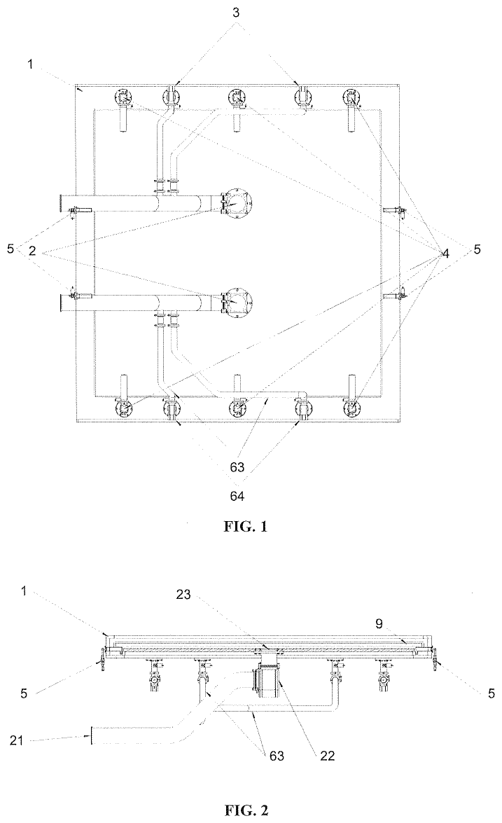

As shown in FIG. 1, the present disclosure discloses a vacuum-pumping and vacuum-breaking structure for large-chamber PECVD, which includes a chamber main body 1. The chamber main body 1 is provided with several main pumping assemblies 2 in the middle of a bottom, both front and rear sides of the bottom of the chamber main body 1 are respectively provided with several slow-vacuum-pumping and vacuum-breaking assemblies 3 and chamber-bottom vacuum-breaking assemblies 4 at intervals, and both left and right sides of the bottom of the chamber main body 1 are respectively provided with side nitrogen vacuum-breaking assemblies 5.

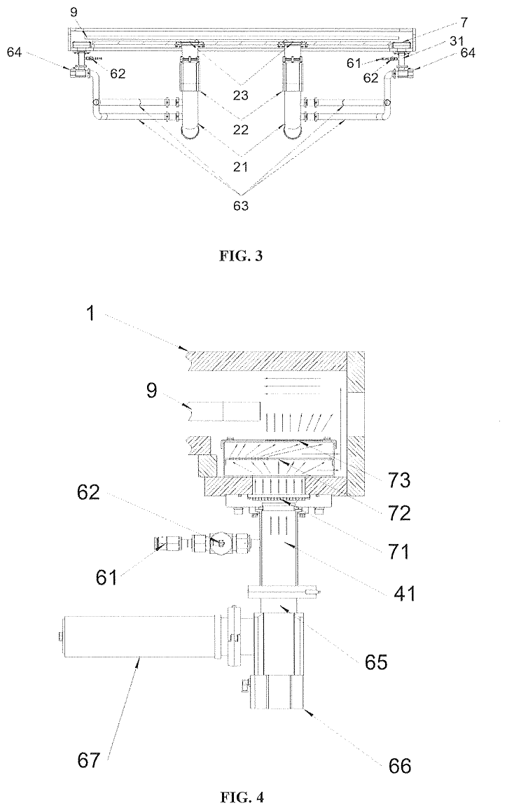

Specifically, as shown in FIG. 1, FIG. 2, and FIG. 3, each of the main pumping assemblies 2 includes a main-pumping pipe 21 and a main-pumping control valve 22. The main-pumping pipe 21 has one end communicating with the chamber main body 1, and the other end communicating with the outside. The main-pumping control valve 22 is provided on the main-pumping pipe 21, and a baffle 23 for filtering is provided at an upper spout of the main-pumping pipe 21.

Specifically, as shown in FIG. 3, each of the slow-vacuum-pumping and vacuum-breaking assemblies 3 includes a first vent pipe 31, the first vent pipe 31 is connected to the chamber, and the first vent pipe 31 is connected to a nitrogen vacuum-breaking pipe 61 and a slow-pumping pipe 63, where the nitrogen vacuum-breaking pipe 61 is provided with a nitrogen vacuum-breaking valve 62, and the slow-pumping pipe 63 is provided with the slow-pumping control valve 64. The slow-pumping pipe 63 and the main-pumping pipe 21 communicate with each other, and are connected to an external aspirator pump.

Specifically, as shown in FIG. 4, each of the chamber-bottom vacuum-breaking assemblies 4 includes a second vent pipe 41, and the second vent pipe 41 is connected to a nitrogen vacuum-breaking pipe 61 and an air vacuum-breaking pipe 65, where the nitrogen vacuum-breaking pipe 61 is provided with a nitrogen vacuum-breaking valve 62, and the air vacuum-breaking pipe 65 is provided with an air vacuum-breaking valve 66 and an air filter 67.

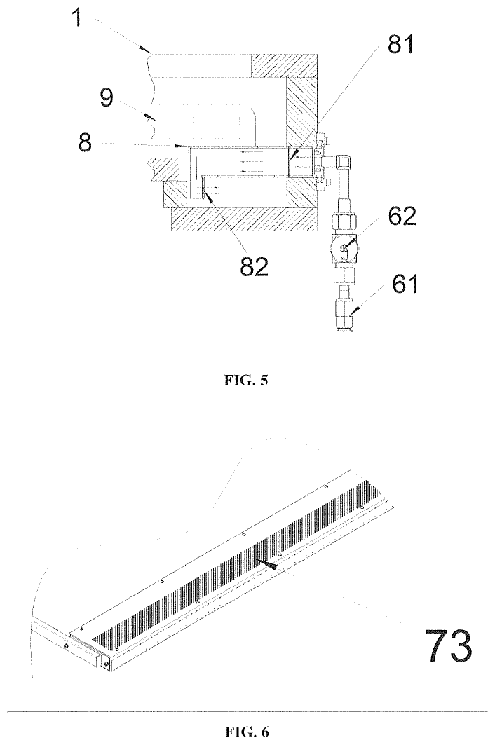

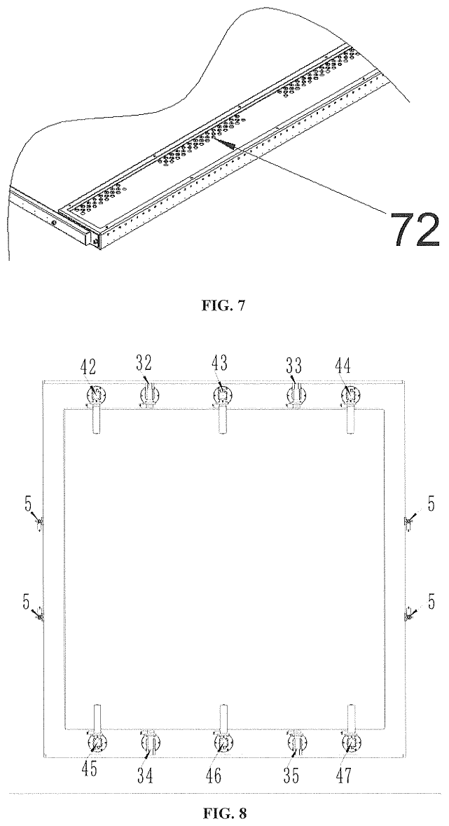

Herein, as shown in FIG. 4, FIG. 6, and FIG. 7, in order to reduce a flow velocity of a gas and disperse the gas into the chamber main body 1 more uniformly, a multi-layer flow-homogenizing assembly 7 is further provided above the first vent pipe 31 and the second vent pipe 41. The multi-layer flow-homogenizing assembly 7 includes a chamber-bottom inlet-gas flow-homogenizing plate 71, a middle-layer flow-homogenizing chamber 72 and an outlet-gas flow-homogenizing chamber 73 that are sequentially stacked from top to bottom. The chamber-bottom inlet-gas flow-homogenizing plate 71 is provided with first flow-homogenizing holes uniformly, and is located on a spout of the first vent pipe 31 and the second vent pipe 41. A top surface of the middle-layer flow-homogenizing chamber 72 is provided with second flow-homogenizing holes 74. A top surface of the outlet-gas flow-homogenizing chamber 73 is provided with third flow-homogenizing holes 75. Herein, the second flow-homogenizing holes 74 and the third flow-homogenizing holes 75 are staggered, so that a gas flow flows in an “S” shape. Three layers of flow-homogenizing chambers have different pore sizes and are staggered in position, which can extend a gas path and reduce a flow velocity at a gas outlet.

Specifically, as shown in FIG. 1 and FIG. 5, each of the side nitrogen vacuum-breaking assemblies 5 includes a nitrogen vacuum-breaking valve 62, a side inlet-gas flow-homogenizing chamber 8 and a nitrogen vacuum-breaking pipe 61, where one end of the nitrogen vacuum-breaking pipe 61 communicates with the chamber through a side flow-homogenizing pipe, and the nitrogen vacuum-breaking valve 62 is provided on the nitrogen vacuum-breaking pipe 61.

Herein, the side flow-homogenizing pipe is in a shape of “L” rotated clockwise by 90 degrees, a side flow-homogenizing plate is provided at a joint of the side flow-homogenizing pipe and the nitrogen vacuum-breaking pipe 61, the side flow-homogenizing plate is provided with several side inlet-gas flow-homogenizing holes 81, and a side surface of a corner of the other end of the side flow-homogenizing pipe is provided with side outlet-gas flow-homogenizing holes 82, where the side outlet-gas flow-homogenizing holes 82 are located below a carrier plate 9, and the gas flow is parallel to a plane of the carrier plate 9. The side flow-homogenizing pipe can discharge an introduced gas from a gas outlet on a side surface of a pipe wall of the side flow-homogenizing pipe, thereby reducing influence on a silicon die.

As shown in FIG. 8, in the present embodiment, two sets of main pumping assemblies 2 are provided, and are distributed symmetrically with respect to a front-rear center line of the chamber.

Four sets of slow-vacuum-pumping and vacuum-breaking assemblies 3 are provided, which are a first slow-vacuum-pumping and vacuum-breaking assembly 32, a second slow-vacuum-pumping and vacuum-breaking assembly 33, a third slow-vacuum-pumping and vacuum-breaking assembly 34, and a fourth slow-vacuum-pumping and vacuum-breaking assembly 35, respectively. Six sets of chamber-bottom vacuum-breaking assemblies 4 are provided, which are a first chamber-bottom vacuum-breaking assembly 42, a second chamber-bottom vacuum-breaking assembly 43, a third chamber-bottom vacuum-breaking assembly 44, a fourth chamber-bottom vacuum-breaking assembly 45, a fifth chamber-bottom vacuum-breaking assembly 46, and a sixth chamber-bottom vacuum-breaking assembly 47, respectively. Four sets of side nitrogen vacuum-breaking assemblies 5 are provided, and are symmetrically provided on left and right sides of the bottom of the chamber main body 1, respectively.

Specifically, the first chamber-bottom vacuum-breaking assembly 42 and the third chamber-bottom vacuum-breaking assembly 44 are respectively located at two ends of a front side of the chamber, and the second chamber-bottom vacuum-breaking assembly 43 is located in the middle of the front side of the chamber.

The fourth chamber-bottom vacuum-breaking assembly 45 and the sixth chamber-bottom vacuum-breaking assembly 47 are located at two ends of a rear side of the chamber, and the fifth chamber-bottom vacuum-breaking assembly 46 is located in the middle of the rear side of the chamber.

The first slow-vacuum-pumping and vacuum-breaking assembly 32 is located between the first chamber-bottom vacuum-breaking assembly 42 and the second chamber-bottom vacuum-breaking assembly 43; the second slow-vacuum-pumping and vacuum-breaking assembly 33 is located between the second chamber-bottom vacuum-breaking assembly 43 and the third chamber-bottom vacuum-breaking assembly 44; the third slow-vacuum-pumping and vacuum-breaking assembly 34 is located between the fourth chamber-bottom vacuum-breaking assembly 45 and the fifth chamber-bottom vacuum-breaking assembly 46; and the fourth slow-vacuum-pumping and vacuum-breaking assembly 35 is located between the fifth chamber-bottom vacuum-breaking assembly 46 and the sixth chamber-bottom vacuum-breaking assembly 47.

When performing vacuum pumping for the chamber main body 1, the slow-pumping control valves 64 are opened first, the gas is evacuated at a small flow rate via the slow-pumping pipes 63 for vacuum pumping, and when an atmosphere in the chamber reaches a certain pressure and the silicon die is stable, the main-pumping control valves 22 are opened, and the gas is rapidly evacuated at a large flow rate via the main-pumping pipes 21 for vacuum pumping.

As shown in FIG. 8, the present embodiment further discloses a vacuum breaking method for the above vacuum-pumping and vacuum-breaking structure for large-chamber PECVD, including steps of:
S1, first, simultaneously opening gates of the nitrogen vacuum-breaking valves 62 of the second chamber-bottom vacuum-breaking assembly 43 and the fifth chamber-bottom vacuum-breaking assembly 46, and introducing small-flow nitrogen from the bottom of the chamber, so that a pressure in the chamber is in a low vacuum state, dither of a silicon die is minimized, and a vacuum-breaking pressure is increased from base vacuum to approximately 100 pa;
S2, simultaneously opening gates of the nitrogen vacuum-breaking valves 62 of the first chamber-bottom vacuum-breaking assembly 42, the third chamber-bottom vacuum-breaking assembly 44, the fourth chamber-bottom vacuum-breaking assembly 45, and the sixth chamber-bottom vacuum-breaking assembly 47, introducing medium-flow nitrogen from the bottom of the chamber, making a gas atmosphere in the chamber uniform, and increasing the vacuum-breaking pressure from 100 Pa to approximately 2,000 Pa;
S3, simultaneously opening gates of the nitrogen vacuum-breaking valves 62 of the four sets of slow-vacuum-pumping and vacuum-breaking assemblies 3, and introducing large-flow nitrogen from the bottom of the chamber, so that the pressure in the chamber rises rapidly, a horizontal flow velocity of the gas is gradually decreased, and the vacuum-breaking pressure is increased from 2,000 Pa to approximately 15,000 Pa;
S4, simultaneously opening gates of the nitrogen vacuum-breaking valves 62 of the four sets of side nitrogen vacuum-breaking assemblies 5, and introducing large-flow nitrogen from side surfaces, so that the pressure in the chamber rises rapidly, a horizontal flow velocity of the gas gradually decreases, and the vacuum-breaking pressure is increased from 15,000 Pa to approximately 30,000 Pa; and
S5, simultaneously opening gates of the air vacuum-breaking valves 66 of the six sets of chamber-bottom vacuum-breaking assemblies 4, introducing large-flow air from the bottom of the chamber, so that the vacuum-breaking pressure is gradually increased from 30,000 pa to atmospheric pressure, thus completing the vacuum breaking.

In conclusion, by changing positions of gas pumping pipe spouts and vacuum-breaking pipe spouts, and designing the positions outside the range of the carrier plate 9, the present disclosure avoids interference with the silicon die during gas pumping and charging, and at the same time, the multi-layer flow-homogenizing assembly 7 is provided on the gas pumping pipe spouts and the vacuum-breaking pipe spouts, so that in the chamber main body 1, the gas will undergo full collision and flow homogenization in the multi-layer flow-homogenizing assembly 7, which extends the gas path, and enables the gas to be uniformly dispersed into the chamber main body 1 at a low flow velocity, thereby minimizing the influence on the silicon die. On this basis, the number of gas pumping pipe spouts and vacuum-breaking pipe spouts can be increased, and vacuum pumping and vacuum breaking are carried out step by step, so that the dither of the silicon die during the vacuum breaking is reduced to a great extent while a vacuum-breaking velocity is increased and the yield is improved.

Preferred embodiments of the present disclosure are described in detail in the above, but the present disclosure is not limited thereto. Within the scope of the technical concept of the present disclosure, a number of simple modifications can be made to the technical solutions of the present disclosure, including combining various technical features in any other suitable ways, and these simple modifications and combinations should also be regarded as contents disclosed in the present disclosure, and all fall within the scope of protection of the present disclosure.

What is claimed is:

1. A vacuum-pumping and vacuum-breaking structure for large-chamber PECVD, comprising a chamber main body, wherein the chamber main body is provided with several main pumping assemblies in the middle of a bottom, both front and rear sides of the bottom of the chamber main body are respectively provided with several slow-vacuum-pumping and vacuum-breaking assemblies and chamber-bottom vacuum-breaking assemblies at intervals,
each of the main pumping assemblies comprises a main-pumping pipe and a main-pumping control valve, wherein the main-pumping pipe has one end communicating with the chamber main body, and the other end communicating with an outside, and the main-pumping control valve is provided on the main-pumping pipe;
each of the slow-vacuum-pumping and vacuum-breaking assemblies comprises a first vent pipe, wherein the first vent pipe is connected to a chamber, and the first vent pipe is connected with a nitrogen vacuum-breaking pipe and a slow-pumping pipe, wherein the nitrogen vacuum-breaking pipe is provided with a nitrogen vacuum-breaking valve, and the slow-pumping pipe is provided with a slow-pumping control valve;
each of the chamber-bottom vacuum-breaking assemblies comprises a second vent pipe, wherein the second vent pipe is connected with a nitrogen vacuum-breaking pipe and an air vacuum-breaking pipe, wherein the nitrogen vacuum-breaking pipe is provided with a nitrogen vacuum-breaking valve, and the air vacuum-breaking pipe is provided with an air vacuum-breaking valve and an air filter; and
a multi-layer flow-homogenizing assembly configured to reduce a flow velocity at a gas outlet is further provided above the first vent pipe and the second vent pipe.

2. The vacuum-pumping and vacuum-breaking structure for large-chamber PECVD according to claim 1, wherein the multi-layer flow-homogenizing assembly comprises a chamber-bottom inlet-gas flow-homogenizing plate, a middle-layer flow-homogenizing chamber and an outlet-gas flow-homogenizing chamber that are sequentially stacked from top to bottom, wherein the chamber-bottom inlet-gas flow-homogenizing plate is provided with first flow-homogenizing holes uniformly, and is located on a spout of the first vent pipe and the second vent pipe, a top surface of the middle-layer flow-homogenizing chamber is provided with second flow-homogenizing holes, a top surface of the outlet-gas flow-homogenizing chamber is provided with third flow-homogenizing holes, and the second flow-homogenizing holes and the third flow-homogenizing holes are staggered, so that a gas flow flows in an “S” shape.

3. The vacuum-pumping and vacuum-breaking structure for large-chamber PECVD according to claim 1, wherein the slow-pumping pipe and the main-pumping pipe communicate with each other, and are connected to an external aspirator pump, and an upper spout of the main-pumping pipe is provide with a baffle for filtering.

4. The vacuum-pumping and vacuum-breaking structure for large-chamber PECVD according to claim 1, wherein both left and right sides of the bottom of the chamber main body are respectively provided with side nitrogen vacuum-breaking assemblies, wherein each of the side nitrogen vacuum-breaking assemblies comprises a nitrogen vacuum-breaking valve, a side inlet-gas flow-homogenizing chamber and a nitrogen vacuum-breaking pipe, wherein one end of the nitrogen vacuum-breaking pipe communicates with the chamber through a side flow-homogenizing pipe, and the nitrogen vacuum-breaking valve is provided on the nitrogen vacuum-breaking pipe.

5. The vacuum-pumping and vacuum-breaking structure for large-chamber PECVD according to claim 4, wherein the side flow-homogenizing pipe is in a shape of “L” rotated clockwise by 90 degrees, a side flow-homogenizing plate is provided at a joint of the side flow-homogenizing pipe and the nitrogen vacuum-breaking pipe, the side flow-homogenizing plate is provided with several side inlet-gas flow-homogenizing holes, and a side surface of a corner of the other end of the side flow-homogenizing pipe is provided with side outlet-gas flow-homogenizing holes, wherein the side outlet-gas flow-homogenizing holes are located below a carrier plate, and a gas flow is parallel to a plane of the carrier plate.

6. The vacuum-pumping and vacuum-breaking structure for large-chamber PECVD according to claim 4, wherein four sets of the side nitrogen vacuum-breaking assemblies are provided, and are symmetrically provided on left and right sides of the bottom of the chamber main body, respectively.

7. The vacuum-pumping and vacuum-breaking structure for large-chamber PECVD according to claim 1, wherein two sets of the main pumping assemblies are provided, and are distributed symmetrically with respect to a front-rear center line of the chamber.

8. The vacuum-pumping and vacuum-breaking structure for large-chamber PECVD according to claim 6, wherein four sets of the slow-vacuum-pumping and vacuum-breaking assemblies are provided, which are a first slow-vacuum-pumping and vacuum-breaking assembly, a second slow-vacuum-pumping and vacuum-breaking assembly, a third slow-vacuum-pumping and vacuum-breaking assembly, and a fourth slow-vacuum-pumping and vacuum-breaking assembly, respectively;
and six sets of the chamber-bottom vacuum-breaking assemblies are provided, which are a first chamber-bottom vacuum-breaking assembly, a second chamber-bottom vacuum-breaking assembly, a third chamber-bottom vacuum-breaking assembly, a fourth chamber-bottom vacuum-breaking assembly, a fifth chamber-bottom vacuum-breaking assembly, and a sixth chamber-bottom vacuum-breaking assembly, respectively;
the first chamber-bottom vacuum-breaking assembly and the third chamber-bottom vacuum-breaking assembly are respectively located at two ends of a front side of the chamber, and the second chamber-bottom vacuum-breaking assembly is located in the middle of the front side of the chamber;
the fourth chamber-bottom vacuum-breaking assembly and the sixth chamber-bottom vacuum-breaking assembly are located at two ends of a rear side of the chamber, and the fifth chamber-bottom vacuum-breaking assembly is located in the middle of the rear side of the chamber; and
the first slow-vacuum-pumping and vacuum-breaking assembly is located between the first chamber-bottom vacuum-breaking assembly and the second chamber-bottom vacuum-breaking assembly; the second slow-vacuum-pumping and vacuum-breaking assembly is located between the second chamber-bottom vacuum-breaking assembly and the third chamber-bottom vacuum-breaking assembly; the third slow-vacuum-pumping and vacuum-breaking assembly is located between the fourth chamber-bottom vacuum-breaking assembly and the fifth chamber-bottom vacuum-breaking assembly; and the fourth slow-vacuum-pumping and vacuum-breaking assembly is located between the fifth chamber-bottom vacuum-breaking assembly and the sixth chamber-bottom vacuum-breaking assembly.

9. A vacuum breaking method for the vacuum-pumping and vacuum-breaking structure for large-chamber PECVD according to claim 8, comprising steps of:
S1, first, simultaneously opening gates of the nitrogen vacuum-breaking valves of the second chamber-bottom vacuum-breaking assembly and the fifth chamber-bottom vacuum-breaking assembly, a vacuum-breaking pressure reaching 100-500 pa;
S2, simultaneously opening gates of the nitrogen vacuum-breaking valves of the first chamber-bottom vacuum-breaking assembly, the third chamber-bottom vacuum-breaking assembly, the fourth chamber-bottom vacuum-breaking assembly, and the sixth chamber-bottom vacuum-breaking assembly, the vacuum-breaking pressure reaching 2,000-2,500 Pa;
S3, simultaneously opening gates of the nitrogen vacuum-breaking valves of four sets of the slow-vacuum-pumping and vacuum-breaking assemblies, the vacuum-breaking pressure reaching 15,000-16,000 Pa;
S4, simultaneously opening the nitrogen vacuum-breaking valves of four sets of the side nitrogen vacuum-breaking assemblies, the vacuum-breaking pressure reaching 30,000 Pa-31,000 Pa; and
S5, simultaneously opening gates of the air vacuum-breaking valves of six sets of the chamber-bottom vacuum-breaking assemblies, the vacuum-breaking pressure reaching atmospheric pressure.
